(19) United States
(12) Patent Application Publication
(10) Pub. No.: US 2003/0066605 A1
(43) Pub. Date: Apr. 10, 2003

(54) Air exhaust system of a chamber for manufacturing semiconductor device

(76) Inventors: Bu-Jin Ko, Daejeon (KR); Jung-Sik Kim, Choongchungnam-do (KR); Sun-Seok Han, Gyeonggi-do (KR)

Correspondence Address: LEWIS F. GOULD, JR., DUANE MORRIS LLP, ONE LIBERTY PLACE, PHILADELPHIA, PA, 19103, US

(21) Appl. No.: 10/264,781

(22) Filed: Oct. 4, 2002

(30) Foreign Application Priority Data
Oct. 9, 2001 (KR) 2001-61984

(51) Int. Cl. C23F 1/00; C23C 16/00

(52) U.S. Cl. 156/345.29; 118/715

(57) ABSTRACT

An air exhaust system of a chamber for manufacturing a semiconductor device comprises a chamber, a chuck formed vertically through a bottom of the chamber, a plurality of openings arranged around the chuck with a same area and a same distance each other, a plurality of outlet ducts having a same area and a length, one end of each of the outlet duct being connected respectively to each of the openings, a buffer system connecting the other end of each of the outlet duct into one, a gate valve connected to the buffer system, an auto pressure controller connected to the gate valve, a turbo pump connected to the auto pressure controller for exhausting gaseous material of an interior of the chamber, and a scrubber connected to the turbo pump for filtering and discharging the gaseous material of the interior of the chamber.

This application claims the benefit of Korean Patent Application No. 2001-61984, filed on Oct. 9, 2001 in Korea, which is hereby incorporated by reference for all purposes as if fully set forth herein.

### BACKGROUND OF THE INVENTION

1. Field of the Invention

The present invention relates to an apparatus for manufacturing a semiconductor device and more particularly, to an air exhaust system that is one of a component of a processing chamber where a wafer is processed.

2. Discussion of the Related Art

A development for a new material has been actively performed in the field and diverse large-scale integrated circuit (LSI) such as ultra large-scale integrated circuit (ULSI) has been developed due to a rapid growth of the new material development. That is, because the new material for forming thin films such as an insulating layer, a semiconductor layer and a conductor layer, which constitute a semiconductor device, has been developed widely in the field, the large-scale integrated circuit (LSI) such as the ultra large-scale integrated (ULSI) circuit is available now. The semiconductor devices are generally fabricated by repeated depositing and patterning process. These processes are accomplished in a manufacturing apparatus of the semiconductor device under vacuum condition.

A chamber type process module may have diverse configurations according to an intended process. A plasma-process chamber type process module will be taken hereinafter for example.

In FIG. 1, the plasma-process chamber type process module 10 includes a chamber 20 where a treatment and a processing of a deposited thin film on a wafer 1 and a gas supply unit 40 which stores and supplies source gases and reaction material for the intended process into the chamber 20. The chamber 20 further includes an inlet duct 23 into which the necessary material that is stored in the gas supply unit 40 flows and an outlet duct 25 that exhausts gaseous material in the chamber 20. The interior of the chamber 20 is divided into a first area 28a and a second area 28b by an insulating plate 26 as shown in the FIG. 1. A part or whole of a plasma generation source 45 is positioned in the first area 28a and a chuck 30 that holds the wafer 1 is positioned in the second area 28b.

The wafer 1 is loaded onto the chuck 30 and then the gaseous source and reaction material stored in the gas supply unit 40 flows through the inlet duct 23 into the chamber 20. The plasma generation source 45 generates plasma in the second area 28b by forming a varying electromagnetic field and thus the wafer 1 can be processed in this circumstance. In the process of the wafer 1 in the chamber 20, many characteristics of the semiconductor element such as uniformity, critical, profile and repeatability is greatly affected by a temperature control of the wafer 1 being processed. Accordingly, the chuck 30 is usually formed movable up and down through the bottom 20a of the chamber 20 and many temperature control systems, though not shown in the figure, such as a bias source controlling an impact energy of the plasma ion and a lift pin drive system for wafer loading and unloading, are built in the chuck 30.

In semiconductor manufacturing process using the plasma-process chamber type process module 10, a reaction condition in the chamber 20 such as a temperature and a pressure should be controlled to be greatly different from those of exterior circumstances of the chamber 20 in order to manufacture a more reliable semiconductor element. Accordingly, the interior of the chamber 20 needs to be in independent reaction condition separated from the exterior of the chamber 20. For this reason, an ordinary air exhaust system 50 is connected to the outlet duct 25 that is an extension of a sidewall 20b of the chamber 20. The air exhaust system 50 controls an interior pressure of the chamber 20 during or before and after the process. The air exhaust system 50 comprises a gate valve 52, an auto pressure controller 54, a turbo pump 56 and a scrubber 58.

To describe a general pressure control process in the chamber 20, when the turbo pump 56 operates after a certain absorption pressure is applied to the turbo pump 56 by the auto pressure controller 54, the gaseous material in the chamber 20 is selectively exhausted through the scrubber 58 by an on-off operation of the gate valve 52. The gaseous material in the chamber 20 goes through a filtering process when it passes through the scrubber 58. To describe it more in detail, when the interior pressure of the chamber 20 needs to be controlled low, the auto pressure controller 54 applies a corresponding absorption pressure to the turbo pump 56 and then the gate valve 52 is turned on. When the gate valve 52 is on, the gaseous material in the chamber 20 passes through the outlet duct 25, the gate valve 52, the auto pressure controller 54 and the turbo pump 56 in a sequence and is finally exhausted through the scrubber 58 in a filtered state. On the other hand, when the interior pressure of the chamber 20 needs to be maintained or increased, the gate valve 52 is turned off and thus the gaseous material in the chamber 20 cannot be exhausted anymore. The source gases and reaction material then inflow through the inlet duct 23 to the chamber 20 to achieve a purpose.

However, this chamber 20 with a conventional air exhaust system 50 has fatal disadvantages as following. That is, the conventional air exhaust system 50 fails to apply a uniform exhaust pressure throughout the interior of the chamber 20 and thus causes an irregular etching of the wafer 1. Because the conventional air exhaust system is formed only at an end of the outlet duct 25 which is extended from an opening 24 that is formed at one sidewall 20b of the chamber 20, an air exhaust pressure distribution of the interior of the chamber 20 becomes leaned toward the opening 24 as shown in FIG. 2.

FIG. 2 shows a cross-section of the interior of the chamber 20 that has the conventional air exhaust system 50. In FIG. 2, the bottom 20a of the chamber 20, a part of the chuck 30 that is formed through the bottom 20a of the chamber 20, the wafer 1 that is loaded on the chuck 30 and the opening 24 that passes through the sidewall 20b of the chamber 20 are illustrated. When the air exhaust system 20, which is formed at the end of the outlet duct 25, is operated to exhaust the interior gas material of the chamber 20, the exhaust pressure of the interior of the chamber 20 is concentrated in area “A” as shown in FIG. 2. This irregular distribution of the exhaust pressure of the interior of the chamber 20 causes the wafer 1 to be etched irregularly. That is, a part of the wafer 1 corresponding to the area “A” is etched more than other parts of the wafer 1. Because this local difference of a degree of etching in wafer 1 gives different electric characteristics to semiconductor cells that are separated from the same wafer 1, it decreases the repeatability and increases a ratio of the inferior goods and thus increases a cost and decreases a manufacturing yield and a reliance of the semiconductor element. These problems are not confined only to the plasma-process chamber type process module, but every kind of the chamber type process module that controls the internal exhaust pressure of the chamber 20 using the conventional air exhaust system 50 formed at only one sidewall of the chamber. In these days, a big size wafer over 300 mm in diameter is widely used in the field in order to improve the manufacturing yield and these problems stated above become much more serious when the big size wafer is used.

### SUMMARY OF THE INVENTION

Accordingly, the present invention is directed to a manufacturing apparatus of a semiconductor device that substantially obviates one or more of problems due to limitations and disadvantages of the related art.

An advantage of the present invention is to provide a manufacturing apparatus of a semiconductor device that has an air exhaust system that can give a uniform exhaust pressure through an interior of a chamber.

Additional features and advantages of the invention will be set forth in the description which follows, and in part will be apparent from the description, or may be learned by practice of the invention. The objectives and other advantages of the invention will be realized and attained by the structure particularly pointed out in the written description and claims hereof as well as the appended drawings.

To achieve these and other advantages and in accordance with the purpose of the present invention, as embodied and broadly described, an air exhaust system of a chamber for manufacturing a semiconductor device comprises a chamber, a chuck formed vertically through a bottom of the chamber, a plurality of openings arranged around the chuck with a same area and a same distance each other, a plurality of outlet ducts having a same area and a length, one end of each of the outlet duct being respectively connected to each of the openings, a buffer system connecting the other end of each of the outlet duct into one, a gate valve connected to the buffer system, an auto pressure controller connected to the gate valve, a turbo pump connected to the auto pressure controller for exhausting gaseous material of an interior of the chamber, and a scrubber connected to the turbo pump for filtering and discharging the gaseous material of the interior of the chamber. A number of the openings and the outlet ducts may respectively be three or five and the air exhaust system may be for a process of a big size wafer that has a diameter over 300 mm. The plurality of the outlet ducts covers around the chuck, which passes through the bottom of the chamber, and is vertically extended from the bottom of the chamber. A buffer chamber is used for the buffer system.

An air exhaust system of a plasma-process chamber type process module for manufacturing a semiconductor device comprises a chamber, an insulating plate dividing the chamber into a first area and a second area, a plasma-process chamber formed in the first area and having a plasma generation source, a chuck formed vertically through a bottom of the chamber, a plurality of openings arranged around the chuck with a same area and a same distance each other, a plurality of outlet ducts having a same area and a length, one end of each of the outlet duct being respectively connected to each of the openings, a buffer system connecting the other end of each of the outlet ducts into one, a gate valve connected to the buffer system, an auto pressure controller connected to the gate valve, a turbo pump connected to the auto pressure controller for exhausting gaseous material of an interior of the chamber, and a scrubber connected to the turbo pump for filtering and discharging the gaseous material of the interior of the chamber.

It is to be understood that both the foregoing general description and the following detailed description are exemplary and explanatory and are intended to provide further explanation of the invention as claimed.

### BRIEF DESCRIPTION OF THE DRAWINGS

The accompanying drawings, which are included to provide a further understanding of the invention and are incorporated in and constitute a part of this specification, illustrate embodiments of the invention and together with the description serve to explain the principles of the invention.

In the drawings:

FIG. 1 is a cross-sectional view of a conventional plasma-process chamber type process module for manufacturing a semiconductor device;

FIG. 2 is a plan view of the chamber to explain a exhaust pressure distribution of an interior of the chamber;

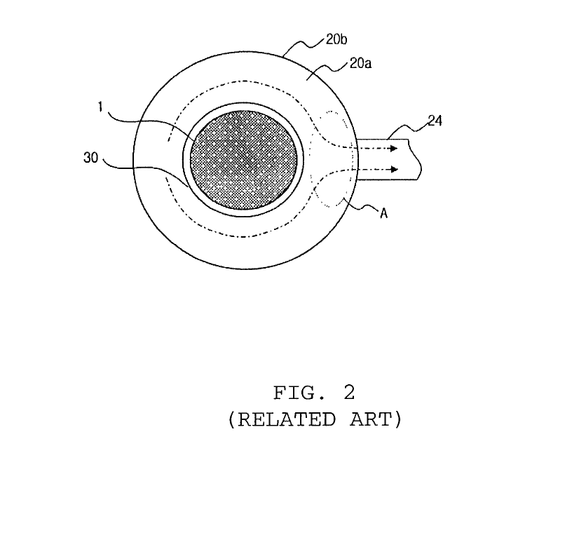

FIG. 3 is a cross-sectional view of a plasma-process chamber type process module for manufacturing a semiconductor device according to the present invention; and

FIG. 4 is a plan view of the chamber to explain an exhaust pressure distribution of an interior of the chamber according to the present invention.

### DETAILED DESCRIPTION OF THE ILLUSTRATED EMBODIMENTS

Reference will now be made in detail to the illustrated embodiment of the present invention, which is illustrated in the accompanying drawings.

An air exhaust system according to the present invention is formed at a chamber, which is a component of a chamber type process module, and supplies a uniform exhaust pressure throughout an interior of the chamber. A plasma-process chamber type process module, which is equipped with the air exhaust system according to the present invention, will be taken hereinafter for explanation.

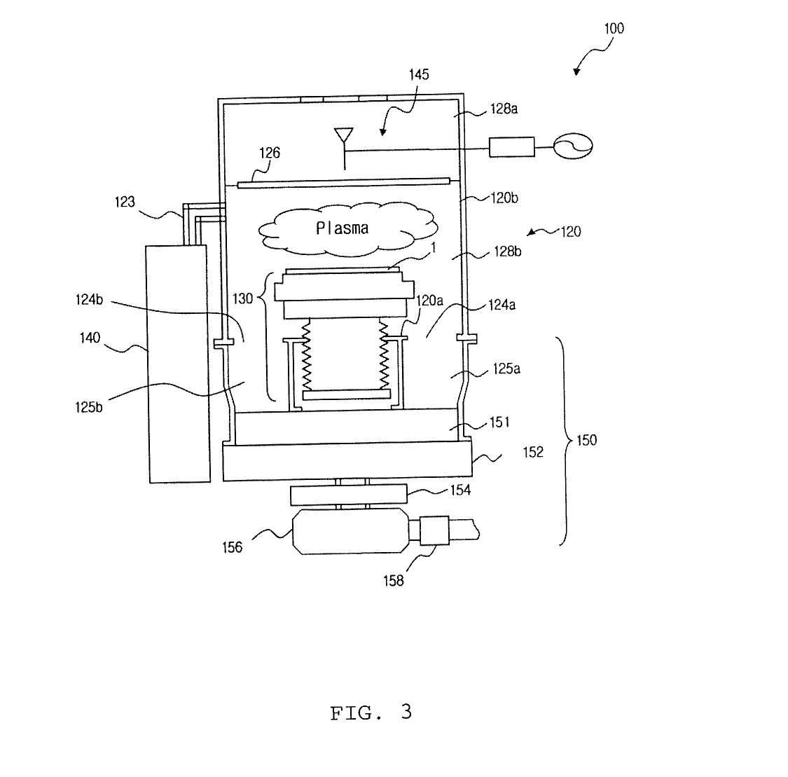

In FIG. 3, the plasma-process chamber type process module 100, which has the air exhaust system according to the present invention, includes a chamber 120 where a process of a thin film on the wafer 1 is occurred and a gas supply unit 140 which stores and supplies source gases and reaction material for the intended process into the chamber 120. The chamber 120 further includes an inlet duct 123 into which a necessary material that is stored in the gas supply unit 140 flows. The interior of the chamber 120 is divided into a first area 128a and a second area 128b by an insulating plate 126 as shown in the FIG. 3. A part or whole of a plasma generation source 145 is positioned in the first area 128a and a chuck 130 that holds the wafer 1 is positioned in the second area 128b.

The wafer 1 is loaded onto the chuck 130 and then the gaseous source and the reaction material stored in the gas supply unit 140 flow through the inlet duct 123 into the chamber 120. The plasma generation source 145 generates plasma in the second area 128b by forming a varying electromagnetic field and thus the wafer 1 can be processed in this circumstance. In the manufacturing process of the wafer 1 in the chamber 120, many characteristics of the semiconductor element such as uniformity, critical, profile and repeatability are greatly affected by a temperature control of the wafer 1 being processed. Accordingly, the chuck 130 is usually formed movable up and down through the bottom 120a of the chamber 120 and many temperature control systems, though not shown in the figure, such as a bias source controlling an impact energy of the plasma ion and a lift pin drive system for a wafer loading and unloading, are built in the chuck 130. The structure of the plasma-process chamber type process module that is described hitherto is same as that of the conventional plasma-process chamber type process module. In a semiconductor manufacturing process using the plasma-process chamber type process module 100, a reaction condition such as a pressure and a temperature of the interior of the chamber 120 should be greatly different from those of the exterior of the chamber 120. The interior pressure of the chamber 120 is controlled lower than that of the exterior of the chamber 120 by the air exhaust system 150 that is formed at the chamber 120.

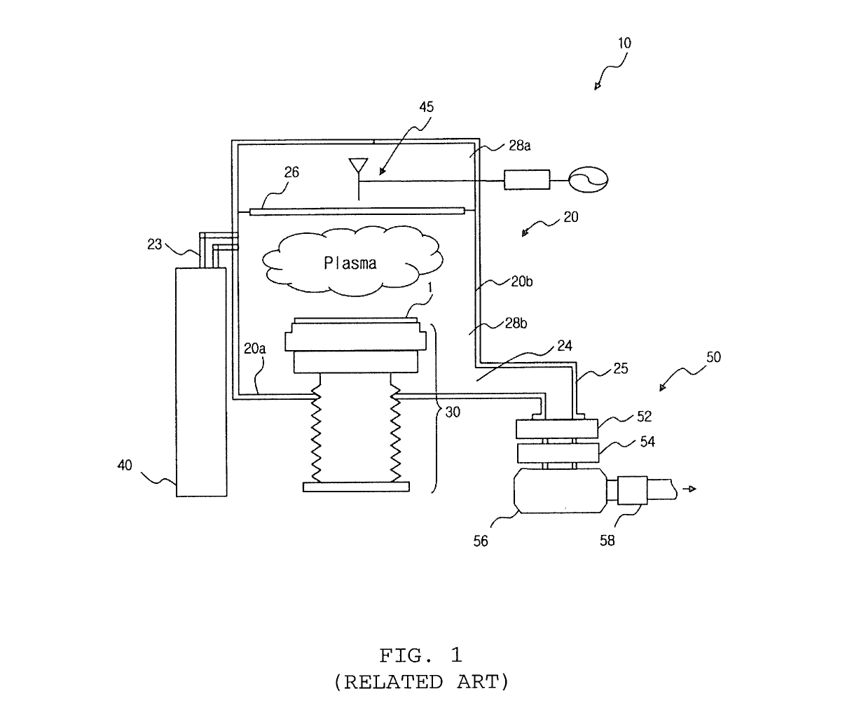

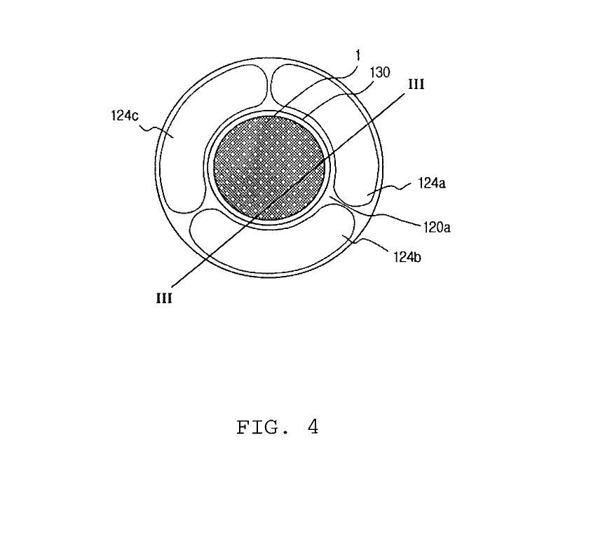

Unlike a conventional air exhaust system 50 in FIG. 1, the air exhaust system of the present invention has a plurality of openings 124a, 124b and 124c that are formed on the bottom of the chamber 120. The air exhaust system 150 is formed through the plurality of openings 124a, 124b and 124c around the chuck and the plurality of openings 124a, 124b and 124c has a same area and a same distance between each other. The chuck is formed through a middle of the bottom 120a of the chamber 120. Though a number of the openings may desirably be three, it can alternatively be more than four according to a desired purpose. Three openings are formed in the present invention, for example, and that is a first opening 124a, a second opening 124b and a third opening 124c. In FIG. 3, only two openings 124a and 124b can be seen because FIG. 3 is a cross-sectional view taken along a line III-III in FIG. 4.

FIG. 4 is a plan view of the chamber to explain an exhaust pressure distribution of an interior of the chamber according to the present invention. In FIG. 4, the bottom 120a of the chamber 120, a part of the chuck 130 that is formed through the bottom 120a of the chamber 120, the wafer 1 that is loaded on the chuck 130 and the first opening 124a, the second opening 124b and the third opening 124c that are formed through the bottom 120a of the chamber 120 are illustrated. Each of the openings 124a, 124b and 124c is respectively connected to one end of a plurality of the outlet ducts 125a, 125b and 125c. Each of the outlet ducts 125a, 125b and 125c are formed vertically to the bottom 120a and desirably has a same area and a same length. Though only the first outlet duct 125a and the second outlet duct 125b are shown in FIG. 4, there are actually three outlet ducts 125a, 125b and 125c in the same way as the openings 124a, 124b and 124c. The outlet ducts 125a, 125b and 125c are arranged around the chuck 130 and the other end of each of the outlet ducts 125a, 125b and 125c is connected to a buffer system 151 that is located under the chuck 130. A gate valve 152, an auto pressure controller 154, a turbo pump 156 and a scrubber 158 are connected in a sequence to the buffer system 151. The buffer system 151 serves to distribute an absorption pressure, which is applied by the turbo pump 156 through the gate valve 152, equally to each of the outlet ducts 125a, 125b and 125c. And a general buffer chamber that serves as a usual buffer may be used for the buffer system 151. The auto pressure controller 154 applies a proper pressure to the turbo pump 156 and the gate valve 152 selectively operates on and off to deliver the absorption pressure to the buffer system 151 or to cutoff the delivery of the absorption pressure to the buffer system 151. Accordingly, the selectively applied absorption pressure of the turbo pump 156 can be applied to the chamber 120 through each of the outlet duct 125a, 125b and 125c and each of the openings 124a, 124b and 124c in a sequence.

To describe an operation of the air exhaust system 150 according to the present invention, the absorption pressure, which is controlled by the auto pressure controller 154, is applied to the turbo pump 156 and then the gate valve operates on or off. The gaseous material of the interior of the chamber 120 is selectively flows into the buffer system 151 through each of the openings 124a, 124b and 124c and each of the outlet ducts 125a, 125b and 125c in a sequence by the selective operation of the gate valve 152. At this time, the buffer system 151 distributes an equal absorption pressure to each of the outlet ducts 125a, 125b and 125c. Because a same absorption pressure is applied through each of the outlet ducts 125a, 125b and 125c and then each of the openings 124a, 124b and 124c, a same amount of the gaseous material of the interior of the chamber 120 flows into the buffer system 151 and then gets mixed in the buffer system 151. The gaseous material is exhausted through the gate valve 152, the turbo pump 156 and finally the scrubber 158 in a sequence. The gaseous material is filtered as it passes through the scrubber 158. When an interior pressure of the chamber 120 needs to be controlled low, the auto pressure controller 154 applies a proper absorption pressure to the turbo pump 156 and then the gate valve 152 is turned on. The gaseous material of the interior of the chamber 120 subsequently flows through each of the outlet ducts 125a, 125b and 125c with a same pressure, the buffer system 151, the gate valve 152 and the turbo pump 156, and is then finally filtered in the scrubber 158. On the other hand when the internal pressure of the chamber 120 needs to be maintained or increased, the gate valve 152 is turned off to stop the delivery of the absorption pressure of the turbo pump 156 to the chamber 120, and thus the internal pressure of the chamber 120 can be maintained. When it is necessary, the internal pressure of the chamber 120 can be increased by supplying gaseous material to the chamber 120 from the gas supply unit 140 through the inlet duct 123.

The application of the air exhaust system of the semiconductor manufacturing chamber according to the present invention is not just limited to the illustrated example, the plasma-process chamber type process module, but it can be applied to all type of chamber when the internal pressure of the chamber needs to be controlled relatively low.

It will be apparent to those skilled in the art that various modifications and variation can be made in the fabrication and application of the present invention without departing from the spirit or scope of the invention. Thus, it is intended that the present invention cover the modifications and variations of this invention provided they come within the scope of the appended claims and their equivalents.

What is claimed is:

1. An air exhaust system of a chamber for manufacturing a semiconductor device, comprising:
a chamber;
a chuck formed vertically through a bottom of the chamber;
a plurality of openings arranged around the chuck with a same area and a same distance each other;
a plurality of outlet ducts having a same area and a length, one end of each of the outlet duct being respectively connected to each of the openings;
a buffer system connecting the other end of each of the outlet duct into one;
a gate valve connected to the buffer system;
an auto pressure controller connected to the gate valve;
a turbo pump connected to the auto pressure controller for exhausting gaseous material of an interior of the chamber; and
a scrubber connected to the turbo pump for filtering and discharging the gaseous material of the interior of the chamber.

2. The air exhaust system according to claim 1, wherein a number of the openings and the outlet ducts is respectively three.

3. The air exhaust system according to claim 1, wherein a number of the openings and the outlet ducts is respectively five.

4. The air exhaust system according to claim 1, wherein the air exhaust system is especially for a process of a big size wafer over 300 mm in diameter.

5. The air exhaust system according to claim 1, wherein the plurality of the outlet ducts covers around the chuck, which is formed through the bottom of the chamber, and is vertically extended from the bottom of the chamber.

6. The air exhaust system according to claim 1, wherein a buffer chamber is used for the buffer system.

7. An air exhaust system of a plasma-process chamber type process module for manufacturing a semiconductor device, comprising:
a chamber;
an insulating plate dividing the chamber into a first area and a second area;
a plasma-process chamber formed in the first area and having a plasma generation source;
a chuck formed vertically through a bottom of the chamber;
a plurality of openings arranged around the chuck with a same area and a same distance each other;
a plurality of outlet ducts having a same area and a length, one end of each of the outlet duct being respectively connected to each of the openings;
a buffer system connecting the other end of each of the outlet duct into one;
a gate valve connected to the buffer system;
an auto pressure controller connected to the gate valve;
a turbo pump connected to the auto pressure controller for exhausting gaseous material of an interior of the chamber; and
a scrubber connected to the turbo pump for filtering and discharging the gaseous material of the interior of the chamber.

8. The air exhaust system according to claim 7, wherein a number of the openings and the outlet ducts is respectively three.

9. The air exhaust system according to claim 7, wherein a number of the openings and the outlet ducts is respectively five.

10. The air exhaust system according to claim 7, wherein the air exhaust system is especially for a process of a big size wafer over 300 mm in diameter.

11. The air exhaust system according to claim 7, wherein the plurality of the outlet ducts covers around the chuck, which is formed through the bottom of the chamber, and is vertically extended from the bottom of the chamber.

12. The air exhaust system according to claim 7, wherein a buffer chamber is used for the buffer system.
